(19) United States
(12) Patent Application Publication
(10) Pub. No.: US 2026/0011687 A1
(43) Pub. Date: Jan. 8, 2026

(54) RADIATION DETECTOR APPARATUS AND SYSTEM

(71) Applicant: TOWER SEMICONDUCTOR LTD., Migdal Haemek (IL)

(72) Inventors: Ruth Shima-Edelstein, Haifa (IL); Yakov Roizin, Afula (IL); Avi Strum, Haifa (IL)

(73) Assignee: TOWER SEMICONDUCTOR LTD., Migdal Haemek (IL)

(21) Appl. No.: 18/765,303

(22) Filed: Jul. 7, 2024

(51) Int. Cl. H01L 25/04; H01L 31/0224; H01L 31/0352

(52) U.S. Cl. CPC H01L 25/042; H10F 77/14; H10F 77/206

(57) ABSTRACT

For example, a sensor die may include a plurality of pixel sensors configured to sense ionizing radiation. The plurality of pixel sensors may include a plurality of detection diodes. For example, the plurality of detection diodes may be in a surface region of a silicon substrate of the sensor die. The plurality of detection diodes may be formed of a diode material. For example, the sensor die may include a plurality of dummy-diode diffusions in the surface region of the silicon substrate. The plurality of dummy-diode diffusions may be in a plurality of gettering regions between the plurality of detection diodes. The plurality of dummy-diode diffusions may include the diode material. For example, a width of the dummy-diode diffusion may be no more than 5 percent of a width of a detection diode of the two adjacent detection diodes.

### BACKGROUND

Radiation detectors may be implemented to detect ionizing radiation.

In one example, radiation detectors may be implemented, for example, as part of medical devices, e.g., as part of a Computed Tomography (CT) scan device.

In another example, radiation detectors may be implemented, for example, as part of nuclear devices, e.g., as part of a particle detector of a particle accelerator.

### BRIEF DESCRIPTION OF THE DRAWINGS

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. The figures are listed below.

FIG. 1 is a schematic block diagram illustration of a radiation detector, in accordance with some demonstrative aspects.

FIG. 2 is a schematic illustration of a first silicided dummy-diode diffusion, a second silicided dummy-diode diffusion, and a third silicided dummy-diode diffusion, in accordance with some demonstrative aspects.

FIG. 3 is a schematic illustration of a dummy-diode diffusion, in accordance with some demonstrative aspects.

FIG. 4 is a schematic illustration of a dummy-diode diffusion, in accordance with some demonstrative aspects.

FIG. 5 is a schematic illustration of a sensor die, in accordance with some demonstrative aspects.

FIG. 6 is a schematic illustration of a cross-section view of a sensor die, and a top-view of a surface region of the sensor die, in accordance with some demonstrative aspects.

FIG. 7 is a schematic illustration of a cross-section view of a sensor die, and a top-view of a surface region of the sensor die, in accordance with some demonstrative aspects.

FIG. 8 is a schematic illustration of a cross-section view of a sensor die, and a top-view of a surface region of the sensor die, in accordance with some demonstrative aspects.

FIG. 9 is a schematic illustration of a cross-section view of a sensor die, and a top-view of a surface region of the sensor die, in accordance with some demonstrative aspects.

FIG. 10 is a schematic illustration of a cross-section view of a sensor die, and a top-view of a surface region of the sensor die, in accordance with some demonstrative aspects.

FIG. 11 is a schematic illustration of a cross-section view of a sensor die, and a top-view of a surface region of the sensor die, in accordance with some demonstrative aspects.

FIG. 12 is a schematic illustration of a cross-section view of a sensor die including a termination area, and a top-view of a surface region of the termination area, in accordance with some demonstrative aspects.

FIG. 13 is a schematic illustration of a cross-section view of a sensor die including a termination area, and a top-view of a surface region of the termination area, in accordance with some demonstrative aspects.

FIG. 14 is a schematic illustration of an electronic device, in accordance with some demonstrative aspects.

### DETAILED DESCRIPTION

In the following detailed description, numerous specific details are set forth in order to provide a thorough understanding of some aspects. However, it will be understood by persons of ordinary skill in the art that some aspects may be practiced without these specific details. In other instances, well-known methods, procedures, components, units, and/or circuits have not been described in detail so as not to obscure the discussion.

Discussions herein utilizing terms such as, for example, “processing”, “computing”, “calculating”, “determining”, “establishing”, “analyzing”, “checking”, or the like, may refer to operation(s) and/or process(es) of a computer, a computing platform, a computing system, or other electronic computing device, that manipulate and/or transform data represented as physical (e.g., electronic) quantities within the computer's registers and/or memories into other data similarly represented as physical quantities within the computer's registers and/or memories or other information storage medium that may store instructions to perform operations and/or processes.

The terms “plurality” and “a plurality”, as used herein, include, for example, “multiple” or “two or more”. For example, “a plurality of items” includes two or more items.

References to “one aspect”, “an aspect”, “demonstrative aspect”, “various aspects” etc., indicate that the aspect(s) so described may include a particular feature, structure, or characteristic, but not every aspect necessarily includes the particular feature, structure, or characteristic. Further, repeated use of the phrase “in one aspect” does not necessarily refer to the same aspect, although it may.

As used herein, unless otherwise specified the use of the ordinal adjectives “first”, “second”, “third” etc., to describe a common object, merely indicate that different instances of like objects are being referred to, and are not intended to imply that the objects so described must be in a given sequence, either temporally, spatially, in ranking, or in any other manner.

The phrases “at least one” and “one or more” may be understood to include a numerical quantity greater than or equal to one, e.g., one, two, three, four, [ . . . ], etc. The phrase “at least one of” with regard to a group of elements may be used herein to mean at least one element from the group consisting of the elements. For example, the phrase “at least one of” with regard to a group of elements may be used herein to mean one of the listed elements, a plurality of one of the listed elements, a plurality of individual listed elements, or a plurality of a multiple of individual listed elements.

The terms “substrate” and/or “wafer”, as used herein, may relate to a thin slice of semiconductor material, for example, a silicon crystal, which may be used in fabrication of integrated circuits and/or any other microelectronic devices. For example, the wafer may serve as the substrate for the microelectronic devices, which may be built in and over the wafer.

The term “Integrated Circuit” (IC), as used herein, may relate to a set of one or more electronic circuits on a semiconductor material. For example, an electronic circuit may include electronic components and their interconnectors.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and/or may represent any information as understood in the art.

The terms “processor” or “controller” may be understood to include any kind of technological entity that allows handling of any suitable type of data and/or information. The data and/or information may be handled according to one or more specific functions executed by the processor or controller. Further, a processor or a controller may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), and the like, or any combination thereof. Any other kind of implementation of the respective functions, which will be described below in further detail, may also be understood as a processor, controller, or logic circuit. It is understood that any two (or more) processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

The term “memory” is understood as a computer-readable medium (e.g., a non-transitory computer-readable medium) in which data or information can be stored for retrieval. References to “memory” may thus be understood as referring to volatile or non-volatile memory, including random access memory (RAM), read-only memory (ROM), flash memory, solid-state storage, magnetic tape, hard disk drive, optical drive, among others, or any combination thereof. Registers, shift registers, processor registers, data buffers, among others, are also embraced herein by the term memory. The term “software” may be used to refer to any type of executable instruction and/or logic, including firmware.

The term “circuitry”, as used herein, may refer to, be part of, or include, an Application Specific Integrated Circuit (ASIC), an integrated circuit, an electronic circuit, a processor (shared, dedicated, or group), and/or memory (shared, dedicated, or group), that execute one or more software or firmware programs, a combinational logic circuit, and/or other suitable hardware components that provide the described functionality. In some aspects, some functions associated with the circuitry may be implemented by one or more software or firmware modules. In some aspects, circuitry may include logic, at least partially operable in hardware.

The term “logic” may refer, for example, to computing logic embedded in circuitry of a computing apparatus and/or computing logic stored in a memory of a computing apparatus. For example, the logic may be accessible by a processor of the computing apparatus to execute the computing logic to perform computing functions and/or operations. In one example, logic may be embedded in various types of memory and/or firmware, e.g., silicon blocks of various chips and/or processors. Logic may be included in, and/or implemented as part of, various circuitry, e.g., radio circuitry, receiver circuitry, control circuitry, transmitter circuitry, transceiver circuitry, processor circuitry, and/or the like. In one example, logic may be embedded in volatile memory and/or non-volatile memory, including random access memory, read only memory, programmable memory, magnetic memory, flash memory, persistent memory, and/or the like. Logic may be executed by one or more processors using memory, e.g., registers, buffers, stacks, and the like, coupled to the one or more processors, e.g., as necessary to execute the logic.

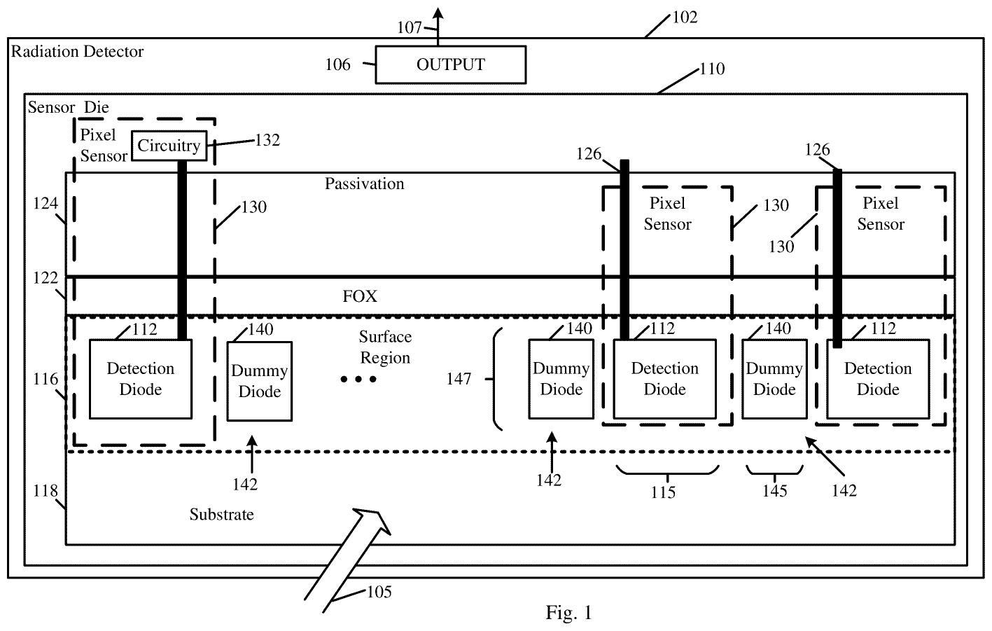

Reference is made to FIG. 1, which schematically illustrates a block diagram of a radiation detector 102, in accordance with some demonstrative aspects.

In some demonstrative aspects, radiation detector 102 may be configured to detect ionizing radiation 105, e.g., as described below.

In some demonstrative aspects, ionizing radiation 105 may include gamma radiation. For example, ionizing radiation 105 may include X-rays.

In one example, radiation detector 102 may be implemented, for example, as part of a medical device, e.g., as part of a Computed Tomography (CT) scan device.

In some demonstrative aspects, ionizing radiation 105 may include energetic particles, e.g., high energy particles.

In one example, radiation detector 102 may be implemented, for example, as part of nuclear devices, e.g., as part of a particle detector of a particle accelerator.

In other aspects, ionizing radiation 105 may include any other suitable additional or alternative type of radiation.

In other aspects, radiation detector 102 may be implemented as part of any other suitable additional or alternative type of device.

In some demonstrative aspects, radiation detector 102 may be configured to provide radiation information 107, for example, based on detected ionizing radiation 105, e.g., as described below.

In some demonstrative aspects, radiation detector 102 may include an output 106, which may be configured to provide the radiation information 107, for example, based on the detected ionizing radiation 105, e.g., as described below.

In some demonstrative aspects, radiation detector 102 may include a sensor die 110, which may be configured to sense the ionizing radiation 105, e.g., as described below.

In some demonstrative aspects, the sensor die 110 may include a plurality of pixel sensors 130, which may be configured to sense the ionizing radiation 105, e.g., as described below.

In some demonstrative aspects, the plurality of pixel sensors 130 may include a plurality of detection diodes 112, which may be configured to detect the ionizing radiation 105, and to generate a plurality of electronic signals based on the detected ionized radiation, for example, of the ionizing radiation 105, e.g., as described below.

In one example, the plurality of detection diodes 112 may be configured to collect, for example, by diffusion and/or by an electric field, electron-hole pairs, which may be created by the ionizing radiation 105.

In some demonstrative aspects, the plurality of detection diodes 112 may be formed of a suitable diode material, e.g., as described below.

In some demonstrative aspects, the diode material may include a heavily doped P-type (P+) material, e.g., as described below.

In some demonstrative aspects, the diode material may include a heavily doped N-type (N+) material, e.g., as described below.

In other aspects, the diode material may include any other suitable material.

In some demonstrative aspects, the plurality of pixel sensors 130 may include a plurality of Active Pixel Sensors (APS) 130, which may be configured to sense the ionizing radiation 105, e.g., as described below.

In some demonstrative aspects, an active pixel sensor 130 of the plurality of active pixel sensors 130 may include electronic circuitry 132 and a detection diode 112 of the plurality of detection diodes 112, e.g., as described below.

In some demonstrative aspects, the electronic circuitry 132 may be configured to process an electronic signal, e.g., of the plurality of electronic signals, which may be generated by the detection diode 112, for example, based on the detected ionizing radiation 105, e.g., as described below.

In some demonstrative aspects, the plurality of detection diodes 112 may be in a surface region 116 of a silicon substrate 118 of the sensor die 110, e.g., as described below.

In some demonstrative aspects, the silicon substrate 118 may include a high-resistance silicon substrate, e.g., as described below.

In some demonstrative aspects, the silicon substrate 118 may include a Float-Zone (FZ) silicon substrate, e.g., as described below.

In some demonstrative aspects, the silicon substrate 118 may include a Czochralski silicon substrate, e.g., as described below.

In other aspects, the silicon substrate 118 may include any other type of high-resistance silicon and/or fully depleted silicon.

In some demonstrative aspects, sensor die 110 may be configured to provide a technical solution to support gettering of impurities in a radiation detector, e.g., radiation detector, utilizing a high-resistance silicon substrate, e.g., silicon substrate 118, for example, an FZ silicon substrate or a Czochralski silicon substrate, e.g., as described below.

In one example, the impurities may include metal contaminants.

For example, the metal contaminants may include any metal material, for example, copper, nickel, iron, cobalt, chromium, and/or the like.

In some demonstrative aspects, sensor die 110 may be configured to provide a technical solution to mitigate an effect of metal contaminants, for example, to mitigate a degradation in performance of radiation detector 102, e.g., due to the metal contaminants, as described below.

In some demonstrative embodiments, radiation sensor 102 may be subject to contamination by the metal contaminants, for example, during a manufacturing process of radiation sensor 102. For example, transition metals, e.g., including copper, iron, nickel, cobalt, and others, may diffuse during thermal processes of an integrated circuit manufacturing, e.g., during manufacturing of one or more integrated circuits of radiation sensor 102.

In some demonstrative aspects, the plurality of detection diodes 112 may be sensitive to the metal contaminants. For example, the metal contaminants may cause one or more damages, defects, and/or the like, e.g., to one or more pixel sensors 130.

In one example, the metal contaminants may precipitate and/or concentrate at a surface of wafers and/or interfaces of the wafers.

For example, the metal contaminants precipitates may result in formation of dislocations and other defects. For example, the metal contaminants precipitates may lead to parasitic charges, for example, even in case of uniform distribution of metal ions at the surfaces.

For example, in some use cases and/or implementations there may be a need to ensure that concentration of impurities at a surface of a wafer, e.g., a production worthy silicon wafer, is to be limited to be much less than 1×10¹¹ atoms per square centimeter (atoms/cm²), for example, in order to avoid defects caused by the metal contaminants.

In some demonstrative aspects, sensor die 110 may be configured to provide a technical solution to support reduced concentration of metal contaminants in active zones of radiation detector 102, which may be fabricated on a high resistance silicon substate, e.g., as described below.

For example, an “active zone” (also referred to as “active area”) may include an area, e.g., on top of a substrate, on which one or more electronic components are integrated. For example, the active area may include one or more integrated electronic components and their interconnectors.

For example, silicon wafers may be manufactured by a process, which may include, e.g., may be started with, a growth of a monocrystalline silicon ingot, for example, based on a Czochralski technology or a FZ technology. For example, a Czochralski silicon substrate may include relatively large amounts of oxygen.

In one example, oxygen may typically form precipitates far from a surface, at which active devices are formed, for example, in case of implementing CMOS technologies on a Czochralski silicon substrate. For example, this phenomenon may be referred to as “intrinsic gettering”.

For example, in some use cases and/or implementations, gettering of metal contaminates may be based on a backside of a wafer (backside gettering). For example, defects at the backside of the wafer may be operable as gettering sites.

However, the backside gettering and/or the intrinsic gettering may not be sufficiently efficient in some cases, e.g., in silicon array detectors on a FZ silicon substrate. For example, the FZ silicon substrate may include negligible amounts of oxygen, which may not allow the intrinsic gettering. For example, the backside gettering and/or the intrinsic gettering may not be sufficiently efficient, for example, in implementations utilizing detection diodes including reverse biased P-type-N-type (P-n) junctions, which may operate at high voltages, e.g., several hundreds of Volts (V), and may require ultra-low leakages.

For example, surface charges related to ambient humidity, and/or charges related to process contaminations may depend on the presence of impurities, and may result in early breakdowns and/or poorer leakage performance of a radiation detector.

For example, the impurities may result in surface charges, surface and bulk defects, and/or may enhance effects connected with moisture-related ion spread at external device surfaces, for example, in the absence of a sufficient gettering mechanism.

For example, some or all of these effects of the metal contaminants may result in increased diode leakage, and/or preliminary breakdown. For example, some or all of these effects of the metal contaminants may result in degraded performance of sensors, for example, sensors employing heavily doped P-type (P+) silicon and lightly doped N-type (−n) (P+−n) silicon diodes, and/or in sensors employing heavily doped N-type (N+) silicon and lightly doped P-type (−p) (N+−p) silicon diodes. For example, some or all of these effects of the metal contaminants may result in degraded performance of the sensors at relatively high voltages on high resistance silicon.

For example, a positive oxide charge may result in surface electron accumulation near an interface of an insulating layer and a bulk.

In one example, a positive oxide charge may short P+ segments of a sensor.

In another example, a negative oxide charge may short N+ segments of a sensor.

In some demonstrative aspects, one or more techniques to mitigate effects of impurities on high-resistive silicon may not be suitable in some use cases, scenarios, and/or implementations, e.g., as described below.

For example, one technique may utilize a P+ field stop implant between N+ segments of a sensor, and/or an N+ field stop implant between P+ segments of the sensor.

For example, another technique may utilize a light doped P-type layer, which may be obtained by applying a p-type spray method, e.g., between the N+ segments of the sensor; and/or a light doped N-type layer, which may be obtained by applying an n-type spray method, e.g., between the P+ segments of the sensor.

For example, another technique may utilize a field plate having a negative potential, e.g., to interrupt an accumulation layer between the N+ segments of the sensor, and/or a field plate having a positive potential, e.g., to interrupt an accumulation layer between the P+ segments of the sensor.

For example, another technique may utilize one or more passivation layers to improve surface current termination.

However, the techniques described above may not be efficient or may be partially efficient, may complicate technology, and/or may increase product cost.

In some demonstrative aspects, one or more techniques, which are based on a high-temperature processing, e.g., above 1100 Celsius degrees, may not be suitable to mitigate effects of impurities on high-resistive silicon in some use cases, scenarios, and/or implementations, e.g., as described below.

In one example, a technique, which may be based on the high-temperature processing, may introduce additional process steps having significant thermal budgets, which may be dangerous for a high resistance FZ silicon substrate. For example, these additional process steps may reduce a sheet resistance, which may be of an order of 10 kilo Ohm per centimeter (kOhm/cm). For example, such a technique including thermal treatments, which may increase a percentage of Hydrogen chloride (HCl) during oxidation, may not be useful.

In some demonstrative aspects, sensor die 110 may be configured to provide a technical solution to support gettering of metal contaminants in active zones of radiation detector 102, which may be fabricated on a silicone substrate, for example, a FZ silicon substrate, or any other suitable type of substrate, e.g., as described below.

For example, the “gettering” of the metal contaminants may include moving, partially or completely, metal impurities from one or more active areas of a substrate to non-active areas of the substrate. For example, the “gettering” of the metal contaminants may include trapping the metal impurities in the non-active areas. The “gettering” of the metal contaminants may have any other additional or alternative effect and/or results.

In some demonstrative aspects, sensor die 110 may be configured to provide a technical solution to support gettering of metal contaminants in active zones of radiation detector 102, which may be fabricated on a silicon substrate, e.g., an FZ silicon substrate, for example, even in case an intrinsic gettering technique is not utilized, e.g., as described below.

In some demonstrative aspects, sensor die 110 may be configured to provide a technical solution to support gettering of metal contaminants in active zones of radiation detector 102, which may be fabricated on a silicon substrate, e.g., an FZ silicon substrate, even in cases where a volume of detection diodes occupies substantially a whole silicon wafer thickness, for example, even in case an intrinsic gettering technique is not utilized, e.g., as described below.

In some demonstrative aspects, sensor die 110 may be configured utilize dummy diode diffusions to provide a technical solution to support gettering of metal contaminants in the active zones of radiation detector 102, which may be fabricated on a silicon substrate, e.g., an FZ silicon substrate, e.g., as described below.

In some demonstrative aspects, the dummy diode diffusions may be arranged between the plurality of pixel sensors 130, e.g., as described below.

In some demonstrative aspects, sensor die 110 may include a plurality of dummy-diode diffusions 140 in the surface region 116 of the silicon substrate 118, e.g., as described below.

In some demonstrative aspects, the plurality of dummy-diode diffusions 140 may be in a plurality of gettering regions 142 between the plurality of detection diodes 112, e.g., as described below.

In some demonstrative aspects, the plurality of dummy-diode diffusions 140 may include the diode material of which the detection diodes 112 are formed, e.g., as described below.

In some demonstrative aspects, a dummy-diode diffusion 140 of the plurality of dummy-diode diffusions 140 in a gettering region 142 between two adjacent detection diodes 112 of the plurality of detection diodes 112 may be configured to getter metal contaminants from the gettering region 142, e.g., as described below.

In some demonstrative aspects, the plurality of dummy-diode diffusions 140 may be configured to provide a technical solution to getter metal contaminants, for example, in manner similar to introducing regions with stresses and/or defects, e.g., as described below.

In some demonstrative aspects, an arrangement of the plurality of dummy-diode diffusions 140 between active pixel sensors 130 may be configured, for example, to provide a technical solution for gettering metal contaminants, e.g., in a manner, which may be useful for array-type X-ray sensors on FZ silicon with detection diodes operating at high voltages, e.g., as described below.

In some demonstrative aspects, a width 145 of the dummy-diode diffusion 140 may be no more than 5 percent of a width 115 of a detection diode 112 of the two adjacent detection diodes 112, e.g., as described below.

In some demonstrative aspects, the width 145 of the dummy-diode diffusion 140 may be no more than 4 percent of the width 115 of the detection diode 112, e.g., as

In some demonstrative aspects, the width 145 of the dummy-diode diffusion 140 may be no more than 3 percent of the width 115 of the detection diode 112, e.g., as described below.

In some demonstrative aspects, the width 145 of the dummy-diode diffusion 140 may be no more than 2 percent of the width 115 of the detection diode 112, e.g., as described below.

In some demonstrative aspects, the width 145 of the dummy-diode diffusion 140 may be no more than 1 percent of the width 115 of the detection diode 112, e.g., as described below.

In some demonstrative aspects, the width 145 of the dummy-diode diffusion 140 may be between 3 micrometer (micron) and 10 micron, e.g., as described below.

In other aspects, any other width of the dummy-diode diffusion 140 may be implemented.

In some demonstrative aspects, a depth 147 of the dummy-diode diffusion 140 may be no more than 10 micron, e.g., as described below.

In some demonstrative aspects, the depth 147 of the dummy-diode diffusion 140 may be no more than 7 micron, e.g., as described below.

In some demonstrative aspects, the depth 147 of the dummy-diode diffusion 140 may be no more than 5 micron, e.g., as described below.

In other aspects, any other depth of the dummy-diode diffusion 140 may be implemented.

In some demonstrative aspects, one or more dummy-diode diffusions 140, e.g., some or all, of the plurality of dummy-diode diffusions 140, may be connected to a Ground (grounded).

In some demonstrative aspects, one or more dummy-diode diffusions 140, e.g., some or all, of the plurality of dummy-diode diffusions 140, may not be connected to the Ground.

In some demonstrative aspects, a thickness of the silicon substrate 118 may be at least 300 micron, e.g., as described below.

In some demonstrative aspects, a thickness of the silicon substrate 118 may be at least 550 micron.

In other aspects, any other thickens of the silicon substrate 118 may be implemented.

In some demonstrative aspects, the dummy-diode diffusion 140 may be at substantially equal distances from the two adjacent detection diodes 112, e.g., as described below.

In some demonstrative aspects, each dummy-diode diffusion 140 of the plurality of dummy-diode diffusions 140 may be in a different gettering region 142 between two different adjacent detection diodes 112 of the plurality of detection diodes 112, e.g., as described below.

In other aspects, at least one gettering region 142 may be configured to include two or more dummy-diode diffusions 140.

In some demonstrative aspects, the plurality of detection diodes 112 may be arranged in a first Two-Dimensional (2D) array, e.g., as described below.

In some demonstrative aspects, the plurality of dummy-diode diffusions 140 may be arranged in a second 2D array, e.g., as described below.

In some demonstrative aspects, the dummy-diode diffusions 140 in the second 2D array may be interleaved with the detection diodes 112 in the first 2D array, e.g., as described below.

In some demonstrative aspects, sensor die 110 may include a Field Oxide (FOX) layer 122 on the surface region 116 of the sensor die 110, e.g., as described below.

In some demonstrative aspects, sensor die 110 may include a passivation layer 124 on the FOX layer 122, e.g., as described below.

In some demonstrative aspects, sensor die 110 may include a plurality of contacts 126 through the passivation layer 124 and the FOX layer 122, e.g., as described below.

In some demonstrative aspects, the plurality of contacts 126 may be connected to the plurality of detection diodes 112, e.g., as described below.

In some demonstrative aspects, at least one dummy-diode diffusion 140 of the plurality of dummy-diode diffusions 140 may include a silicided dummy-diode diffusion, e.g., as described below.

In some demonstrative aspects, the silicided dummy-diode diffusion may include a dummy-diode portion including the diode material, e.g., as described below.

In some demonstrative aspects, the silicided dummy-diode diffusion may include a silicide layer (not shown in FIG. 1) on the dummy-diode portion, e.g., as described below.

For example, the “silicide” may include a chemical compound of silicon with one or more relatively more electropositive elements, e.g., metal and/or any other element.

In some demonstrative aspects, the silicide layer may be formed of Cobalt Silicide (CoSi), e.g., as described below.

In some demonstrative aspects, the silicide layer may be formed of Titanium Silicide (TiSi), e.g., as described below.

In some demonstrative aspects, the silicide layer may be formed of Nickel Silicide (NiSi), e.g., as described below.

In other aspects, the silicide layer may be formed of any other additional and/or alternative silicide material.

In some demonstrative aspects, the dummy-diode portion of the silicided dummy-diode diffusion may include a trench (not shown in FIG. 1), e.g., as described below.

In some demonstrative aspects, the silicide layer of the silicided dummy-diode diffusion may include an aperture (not shown in FIG. 1) over the trench, e.g., as

In some demonstrative aspects, the dummy-diode portion of the silicided dummy-diode diffusion may include a bulbous cavity (not shown in FIG. 1), e.g., as described below.

In some demonstrative aspects, the silicide layer of the silicided dummy-diode diffusion may include an aperture (not shown in FIG. 1) over the bulbous cavity, e.g., as described below.

In some demonstrative aspects, the FOX layer 122 on the surface region 116 of the silicon substrate 118 may have an opening (not shown in FIG. 1) above the silicided dummy-diode diffusion, e.g., as described below.

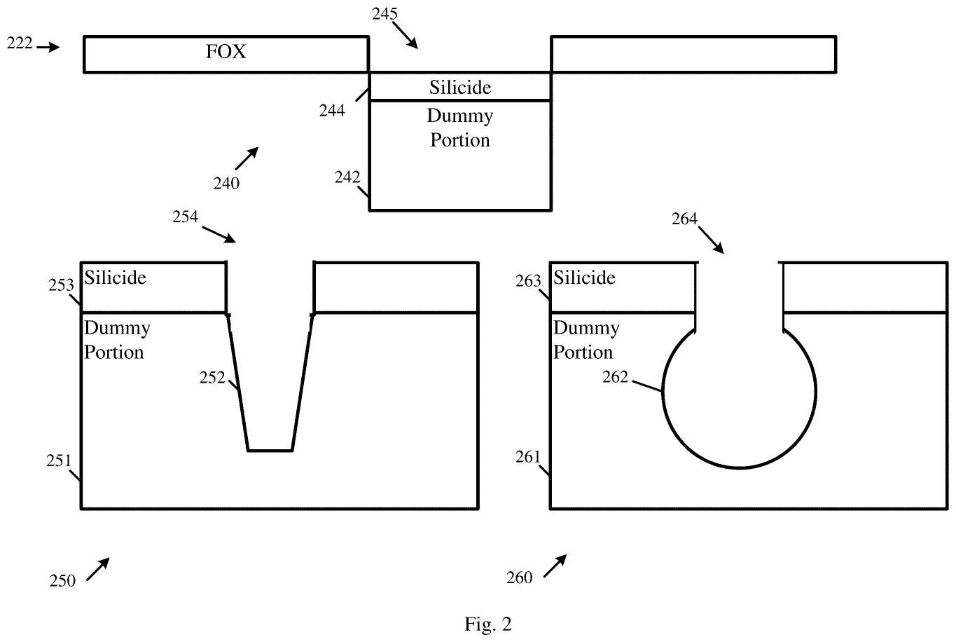

Reference is made to FIG. 2, which schematically illustrates a first silicided dummy-diode diffusion 240, a second silicided dummy-diode diffusion 250, and a third silicided dummy-diode diffusion 260, in accordance with some demonstrative aspects. For example, the plurality of dummy-diode diffusions 140 (FIG. 1) may include one or more elements of the silicided dummy-diode diffusion 240, the silicided dummy-diode diffusion 250, and/or the silicided dummy-diode diffusion 260.

In some demonstrative aspects, as shown in FIG. 2, silicided dummy-diode diffusion 240 may include a dummy-diode portion 242 including the diode material, e.g., as described below.

In some demonstrative aspects, as shown in FIG. 2, silicided dummy-diode diffusion 240 may include a silicide layer 244 on the dummy-diode portion 242, e.g., as described below.

In some demonstrative aspects, as shown in FIG. 2, a FOX layer 222, which may be on a surface region including the dummy-diode diffusion 240, e.g., surface region 116 (FIG. 1), may have an opening 245 above the silicided dummy-diode diffusion 240.

In some demonstrative aspects, as shown in FIG. 2, silicided dummy-diode diffusion 250 may include a dummy-diode portion 251 including the diode material, e.g., as described below.

In some demonstrative aspects, as shown in FIG. 2, silicided dummy-diode diffusion 250 may include a silicide layer 253 on the dummy-diode portion 251, e.g., as described below.

In some demonstrative aspects, as shown in FIG. 2, the dummy-diode portion 251 of the silicided dummy-diode diffusion 250 may include a trench 252, e.g., as described below.

In some demonstrative aspects, as shown in FIG. 2, the silicide layer 253 of the silicided dummy-diode diffusion 250 may include an aperture 254 over the trench 252, e.g., as described below.

In other aspects, the silicide layer 253 of the silicided dummy-diode diffusion 250 may be configured to at least partially cover the trench 252, for example, the silicide layer 253 of the silicided dummy-diode diffusion 250 may not include the aperture 254 over the trench 252.

In some demonstrative aspects, the trench 252 may be formed, for example, by an initial silicide etch process, followed by a Silicon (Si) etch process.

In other aspects, the trench 252 may be formed by any other additional and/or alternative process.

In some demonstrative aspects, as shown in FIG. 2, silicided dummy-diode diffusion 260 may include a dummy-diode portion 261 including the diode material, e.g., as described below.

In some demonstrative aspects, as shown in FIG. 2, silicided dummy-diode diffusion 260 may include a silicide layer 263 on the dummy-diode portion 261, e.g., as described below.

In some demonstrative aspects, as shown in FIG. 2, the dummy-diode portion 241 of the silicided dummy-diode diffusion 260 may include a bulbous cavity 262, e.g., as described below.

In some demonstrative aspects, as shown in FIG. 2, the silicide layer 263 of the silicided dummy-diode diffusion 260 may include an aperture 264 over the bulbous cavity 262, e.g., as described below.

In other aspects, the silicide layer 263 of the silicided dummy-diode diffusion 260 may be configured to at least partially cover the bulbous cavity 262, for example, the silicide layer 263 of the silicided dummy-diode diffusion 260 may not include the aperture 264 over the bulbous cavity 262.

In some demonstrative aspects, bulbous cavity 262 may be formed, for example, by an initial anisotropic silicon etch process, which may form a “pipe” in the silicon substrate 118 (FIG. 1).

In some demonstrative aspects, the initial anisotropic silicon etch process may be followed by a resist strip and ashing processes, and a formation of a liner in the pipe, which may serve as a protective hard mask for a subsequent second isotropic etch in the silicone. For example, the subsequent second isotropic etch in the silicone may form the bulbous cavity 262.

In some demonstrative aspects, the protective hard mask may be removed, and a field oxide may be grown on the bulbous cavity 262.

In other aspects, the bulbous cavity 262 may be formed by any other additional and/or alternative process.

Referring back to FIG. 1, in some demonstrative aspects, at least one dummy-diode diffusion 140 of the plurality of dummy-diode diffusions 140 may include a trench (not shown in FIG. 1), e.g., as described below.

In some demonstrative aspects, the trench may be substantially in the middle of the dummy-diode diffusion 140, e.g., as described below.

In some demonstrative aspects, a width of the trench may be no more than 1 micron, e.g., as described below.

In some demonstrative aspects, the width of the trench may be no more than 0.7 micron, e.g., as described below.

In some demonstrative aspects, the width of the trench may be no more than 0.5 micron, e.g., as described below.

In some demonstrative aspects, the width of the trench may be no more than 0.4 micron, e.g., as described below.

In some demonstrative aspects, the width of the trench may be between 0.3 micron and 1 micron, e.g., as described below.

In other aspects, the trench may have any other width.

In some demonstrative aspects, a depth of the trench may be no more than 3 micron, e.g., as described below.

In some demonstrative aspects, the depth of the trench may be no more than 2 micron, e.g., as described below.

In some demonstrative aspects, the depth of the trench may be no more than 1 micron, e.g., as described below.

In some demonstrative aspects, the depth of the trench may be no more than 0.5 micron, e.g., as described below.

In some demonstrative aspects, the depth of the trench may be between 0.5 micron and 3 micron, e.g., as described below.

In other aspects, the trench may have any other depth.

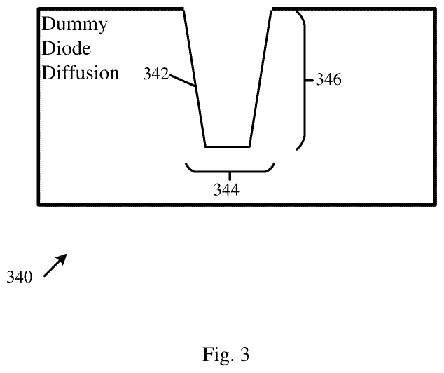

Reference is made to FIG. 3, which schematically illustrates a dummy-diode diffusion 340, in accordance with some demonstrative aspects. For example, at least one dummy diode diffusion 140 (FIG. 1) of the plurality of dummy-diode diffusions 140 (FIG. 1) may include one or more elements of dummy-diode diffusion 340.

In some demonstrative aspects, as shown in FIG. 3, dummy-diode diffusion 340 may include a trench 342.

In some demonstrative aspects, as shown in FIG. 3, the trench 342 may be substantially in the middle of the dummy-diode diffusion 340.

In some demonstrative aspects, a width 344 of the trench 342 may be no more than 1 micron.

In some demonstrative aspects, the width 344 of the trench 342 may be no more than 0.7 micron, e.g., as described below.

In some demonstrative aspects, the width 344 of the trench 342 may be no more than 0.5 micron.

In some demonstrative aspects, the width 344 of the trench 342 may be no more than 0.4 micron.

In some demonstrative aspects, the width 344 of the trench 342 may be between 0.3 micron and 1 micron.

In other aspects, the trench 342 may have any other width.

In some demonstrative aspects, a depth 346 of the trench 342 may be no more than 3 micron.

In some demonstrative aspects, the depth 346 of the trench 342 may be no more than 2 micron.

In some demonstrative aspects, the depth 346 of the trench 342 may be no more than 1 micron.

In some demonstrative aspects, the depth 346 of the trench 342 may be no more than 0.5 micron.

In some demonstrative aspects, depth 346 of the trench 342 may be between 0.5 micron and 3 micron.

In other aspects, the trench 342 may have any other depth.

In some demonstrative aspects, the trench 342 may be formed, for example, by an initial silicide etch process, followed by a Silicon (Si) etch process.

In other aspects, the trench 342 may be formed by any other additional and/or alternative process.

Referring back to FIG. 1, in some demonstrative aspects, at least one dummy-diode diffusion 140 of the plurality of dummy-diode diffusions 140 may include a bulbous cavity (also referred to as “bulbous hollow”) (not shown in FIG. 1), e.g., as described below.

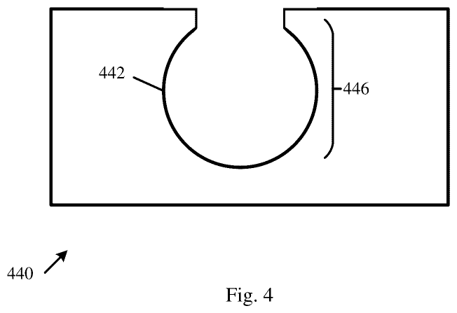

Reference is made to FIG. 4, which schematically illustrates a dummy-diode diffusion 440, in accordance with some demonstrative aspects. For example, at least one dummy-diode diffusion 140 (FIG. 1) of the plurality of dummy-diode diffusions 140 may include one or more elements of dummy-diode diffusion 440.

In some demonstrative aspects, as shown in FIG. 4, dummy-diode diffusion 440 may include a bulbous cavity 442.

In some demonstrative aspects, as shown in FIG. 4, the bulbous cavity 442 may be substantially in the middle of the dummy-diode diffusion 440.

In some demonstrative aspects, a depth 446 of the bulbous cavity 442 may be no more than 4 micron.

In some demonstrative aspects, a depth 446 of the bulbous cavity 442 may be no more than 3 micron.

In some demonstrative aspects, the depth 446 of the bulbous cavity 442 may be no more than 2 micron.

In some demonstrative aspects, a depth 446 of the bulbous cavity 442 may be no more than 1 micron.

In some demonstrative aspects, a depth 446 of the bulbous cavity 442 may be no more than 0.5 micron.

In some demonstrative aspects, the depth 446 of the bulbous cavity 442 may be between 0.5 micron and 4 micron.

In other aspects, the bulbous cavity 442 may have any other depth.

In some demonstrative aspects, bulbous cavity 442 may be formed, for example, by an initial anisotropic silicon etch process, which may form a “pipe” in the silicon substrate 118 (FIG. 1).

In some demonstrative aspects, the initial anisotropic silicon etch process may be followed by a resist strip and ashing processes, and a formation of a liner in the pipe, which may serve as a protective hard mask for a subsequent second isotropic etch in the silicone. For example, the subsequent second isotropic etch in the silicone may form the bulbous cavity 442.

In some demonstrative aspects, the protective hard mask may be removed, and a field oxide may be grown on the bulbous cavity 442.

In other aspects, the bulbous cavity 442 may be formed by any other additional and/or alternative process.

Referring back to FIG. 1, in some demonstrative aspects, the sensor die 110 may include a plurality of termination diffusions (not shown in FIG. 1) in a termination area of the sensor die 110, e.g., as described below.

In some demonstrative aspects, at least one termination diffusion of the plurality of termination diffusions may be configured as a contaminant-gettering termination diffusion, for example, to getter metal contaminants from the termination area, e.g., as described below.

In some demonstrative aspects, the at least one contaminant-gettering termination diffusion may include a collection guard-ring, e.g., as described below.

In some demonstrative aspects, the at least one contaminant-gettering termination diffusion may include a floating diffusion ring, e.g., as described below.

In some demonstrative aspects, the at least one contaminant-gettering termination diffusion may include a field stop diffusion, e.g., as described below.

In other aspects, the at least one contaminant-gettering termination diffusion may include any other type of termination diffusion.

In some demonstrative aspects, the contaminant-gettering termination diffusion may include a trench (not shown in FIG. 1), e.g., as described below.

In some demonstrative aspects, the contaminant-gettering termination diffusion may include a bulbous cavity (not shown in FIG. 1), e.g., as described below.

In some demonstrative aspects, the contaminant-gettering termination diffusion may include a silicided contaminant-gettering termination diffusion (not shown in FIG. 1), e.g., as described below.

In some demonstrative aspects, the silicided contaminant-gettering termination diffusion may include a termination portion, e.g., as described below.

In some demonstrative aspects, the silicided contaminant-gettering termination diffusion may include a silicide layer on the termination portion, e.g., as

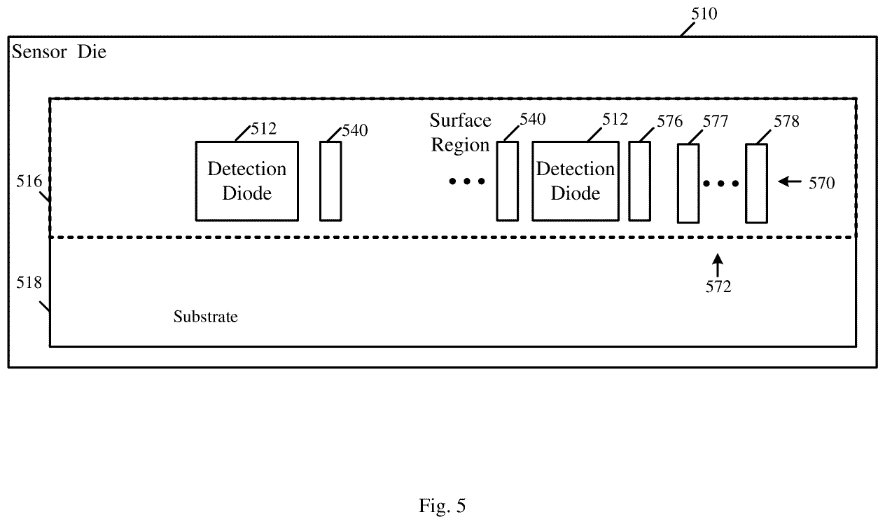

Reference is made to FIG. 5, which schematically illustrates a sensor die 510, in accordance with some demonstrative embodiments. For example, sensor die 110 (FIG. 1) may include one or more elements of sensor die 510.

In some demonstrative aspects, as shown in FIG. 5, sensor die 510 may include a plurality of pixel sensors including a plurality of detection diodes 512.

In some demonstrative aspects, as shown in FIG. 5, the plurality of detection diodes 512 may be in a surface region 516 of a silicon substrate 518 of the sensor die 510.

In some demonstrative aspects, as shown in FIG. 5, sensor die 510 may include a plurality of dummy-diode diffusions 540 in the surface region 516, for example, between the plurality of detection diodes 512.

In some demonstrative aspects, as shown in FIG. 5, sensor die 510 may include a plurality of termination diffusions 570 in a termination area 572 of the sensor die 510.

In some demonstrative aspects, at least one termination diffusion 570 of the plurality of termination diffusions 570 may be configured as a contaminant-gettering termination diffusion, for example, to getter metal contaminants from the termination area 572.

In some demonstrative aspects, the at least one contaminant-gettering termination diffusion 570 may include a collection guard-ring 576.

In some demonstrative aspects, the at least one contaminant-gettering termination diffusion 570 may include a floating diffusion ring 577.

In some demonstrative aspects, the at least one contaminant-gettering termination diffusion 570 may include a field stop diffusion 578.

In other aspects, the at least one contaminant-gettering termination diffusion 570 may include any other type of termination diffusion.

In some demonstrative aspects, the contaminant-gettering termination diffusion 570 may include a trench (not shown in FIG. 5), e.g., as described below.

In some demonstrative aspects, the contaminant-gettering termination diffusion 570 may include a bulbous cavity (not shown in FIG. 5), e.g., as described below.

In one example, one or more bulbous cavities and/or one or more trenches may be implemented in one or more floating diffusion rings 577, for example, to provide a technical solution to reduce a number of floating rings, and/or to reduce a size of termination area 572, e.g., a sensor dead region size.

In some demonstrative aspects, the contaminant-gettering termination diffusion 570 may include a silicided contaminant-gettering termination diffusion (not shown in FIG. 1).

In some demonstrative aspects, the silicided contaminant-gettering termination diffusion may include a termination portion and a silicide layer on the termination portion.

In one example, the silicide layer may include silicide layer 244 (FIG. 2).

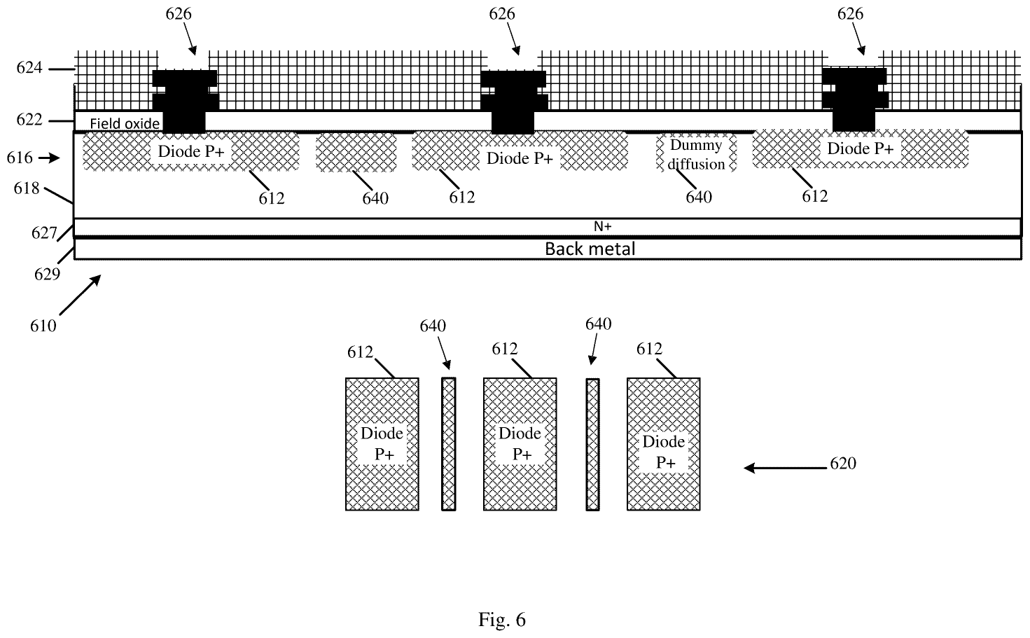

Reference is made to FIG. 6, which schematically illustrates a cross-section view of a sensor die 610, and a top-view 620 of a surface region 616 of the sensor die 610, in accordance with some demonstrative embodiments. For example, sensor die 110 (FIG. 1) may include one or more elements of sensor die 610.

In some demonstrative aspects, as shown in FIG. 6, sensor die 610 may include a plurality of detection diodes 612, which include a diode material, in the surface region 616 of a silicon substrate 618 of the sensor die 610.

In some demonstrative aspects, as shown in FIG. 6, sensor die 610 may include a plurality of dummy-diode diffusions 640 in the surface region 616, for example, between the plurality of detection diodes 612.

In some demonstrative aspects, as shown in FIG. 6, sensor die 610 may include a FOX layer 622 on the surface region 616 of the sensor die 610.

In some demonstrative aspects, as shown in FIG. 6, sensor die 610 may include a passivation layer 624 on the FOX layer 622.

In some demonstrative aspects, as shown in FIG. 6, sensor die 610 may include a plurality of contacts 626, which may be connected to the detection diodes 612, for example, through the passivation layer 624 and the FOX layer 622.

In some demonstrative aspects, as shown in FIG. 6, sensor die 610 may include an N+ layer 627 on the silicon substrate 618.

In some demonstrative aspects, as shown in FIG. 6, sensor die 610 may include a back-metal layer 629 on the N+ layer 627.

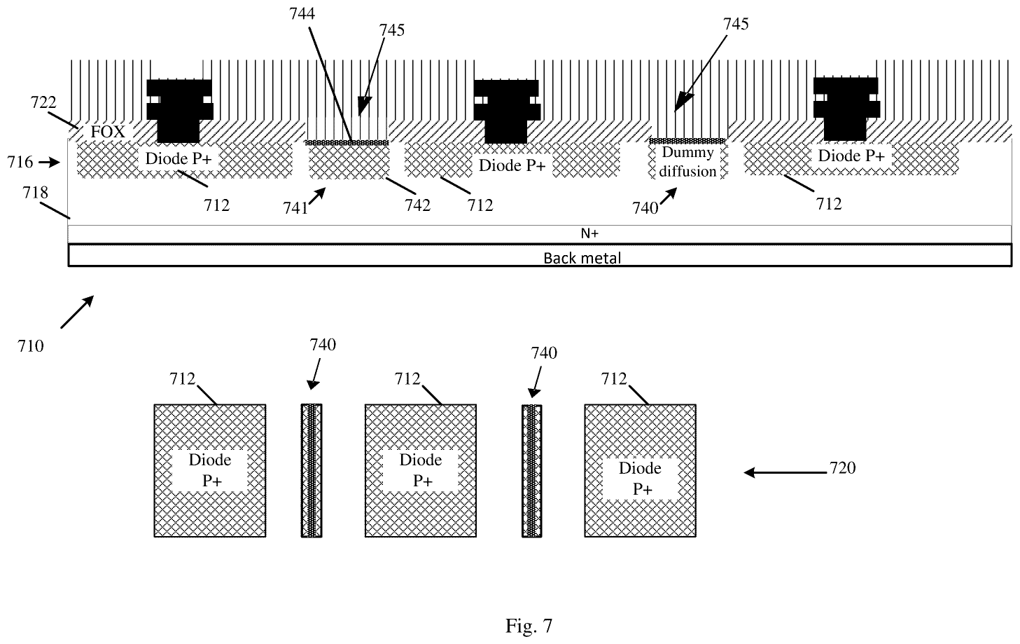

Reference is made to FIG. 7, which schematically illustrates a cross-section view of a sensor die 710, and a top-view 720 of a surface region 716 of the sensor die 710, in accordance with some demonstrative embodiments. For example, sensor die 110 (FIG. 1) may include one or more elements of sensor die 710.

In some demonstrative aspects, as shown in FIG. 7, sensor die 710 may include a plurality of detection diodes 712, which include a diode material, in the surface region 716 of a silicon substrate 718 of the sensor die 710.

In some demonstrative aspects, as shown in FIG. 7, sensor die 710 may include a plurality of dummy-diode diffusions 740 including the diode material.

In some demonstrative aspects, as shown in FIG. 7, the plurality of dummy-diode diffusions 740 may be in the surface region 716, for example, between the plurality of detection diodes 712.

In some demonstrative aspects, as shown in FIG. 7, a dummy-diode diffusion 741 of the plurality of dummy-diode diffusions 740, e.g., each dummy-diode diffusion 740, may include a silicided dummy-diode diffusion 741.

In some demonstrative aspects, as shown in FIG. 7, silicided dummy-diode diffusion 741 may include a dummy-diode portion 742 including the diode material.

In some demonstrative aspects, as shown in FIG. 7, silicided dummy-diode diffusion 741 may include a silicide layer 744 on the dummy-diode portion 742, e.g., as described below.

In some demonstrative aspects, as shown in FIG. 7, a FOX layer 722, which may be on the surface region 716 of the silicon substrate 718, may have an opening 745 above the silicided dummy-diode diffusions 741.

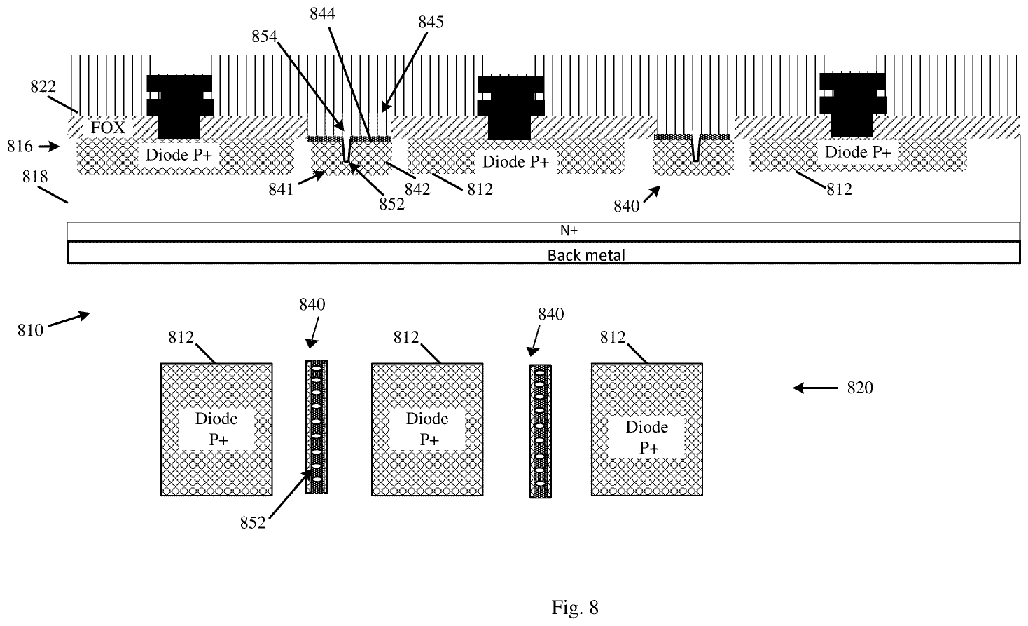

Reference is made to FIG. 8, which schematically illustrates a cross-section view of a sensor die 810, and a top-view 820 of a surface region 816 of the sensor die 810, in accordance with some demonstrative embodiments. For example, sensor die 110 (FIG. 1) may include one or more elements of sensor die 810.

In some demonstrative aspects, as shown in FIG. 8, sensor die 810 may include a plurality of detection diodes 812, which include a diode material, in the surface region 816 of a silicon substrate 818 of the sensor die 810.

In some demonstrative aspects, as shown in FIG. 8, sensor die 810 may include a plurality of dummy-diode diffusions 840 including the diode material.

In some demonstrative aspects, as shown in FIG. 8, the plurality of dummy-diode diffusions 840 may be in the surface region 816, for example, between the plurality of detection diodes 812.

In some demonstrative aspects, as shown in FIG. 8, a dummy-diode diffusion 841 of the plurality of dummy-diode diffusions 840, e.g., each dummy-diode diffusion 840, may include a silicided dummy-diode diffusion 841.

In some demonstrative aspects, as shown in FIG. 8, silicided dummy-diode diffusion 841 may include a dummy-diode portion 842 including the diode material.

In some demonstrative aspects, as shown in FIG. 8, silicided dummy-diode diffusion 841 may include a silicide layer 844 on the dummy-diode portion 842.

In some demonstrative aspects, as shown in FIG. 8, silicided dummy-diode diffusion 841 may include a trench 852.

In some demonstrative aspects, as shown in FIG. 8, the silicide layer 844 of the silicided dummy-diode diffusion 840 may include an aperture 854 over the trench 852.

In some demonstrative aspects, as shown in FIG. 8, a FOX layer 822, which may be on the surface region 816 of the silicon substrate 818, may have an opening 845 above the silicided dummy-diode diffusions 841.

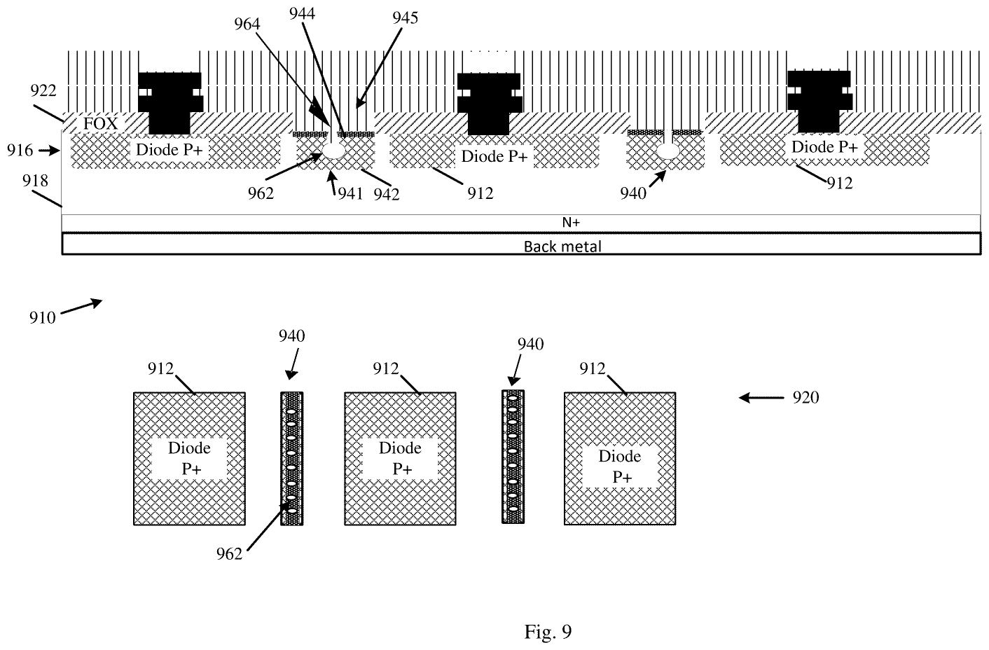

Reference is made to FIG. 9, which schematically illustrates a cross-section view of a sensor die 910, and a top-view 920 of a surface region 916 of the sensor die 910, in accordance with some demonstrative embodiments. For example, sensor die 110 (FIG. 1) may include one or more elements of sensor die 910.

In some demonstrative aspects, as shown in FIG. 9, sensor die 910 may include a plurality of detection diodes 912, which include a diode material, in the surface region 916 of a silicon substrate 918 of the sensor die 910.

In some demonstrative aspects, as shown in FIG. 9, sensor die 910 may include a plurality of dummy-diode diffusions 940 including the diode material.

In some demonstrative aspects, as shown in FIG. 9, the plurality of dummy-diode diffusions 940 may be in the surface region 916, for example, between the plurality of detection diodes 912.

In some demonstrative aspects, as shown in FIG. 9, a dummy-diode diffusion 941 of the plurality of dummy-diode diffusions 940, e.g., each dummy-diode diffusion 940, may include a silicided dummy-diode diffusion 941.

In some demonstrative aspects, as shown in FIG. 9, silicided dummy-diode diffusion 941 may include a dummy-diode portion 942 including the diode material.

In some demonstrative aspects, as shown in FIG. 9, silicided dummy-diode diffusion 941 may include a silicide layer 944 on the dummy-diode portion 942.

In some demonstrative aspects, as shown in FIG. 9, silicided dummy-diode diffusion 941 may include a bulbous cavity 962.

In some demonstrative aspects, as shown in FIG. 9, the silicide layer 944 of the silicided dummy-diode diffusion 940 may include an aperture 964 over the bulbous cavity 962.

In some demonstrative aspects, as shown in FIG. 9, a FOX layer 922, which may be on the surface region 916 of the silicon substrate 918, may have an opening 945 above the silicided dummy-diode diffusions 941.

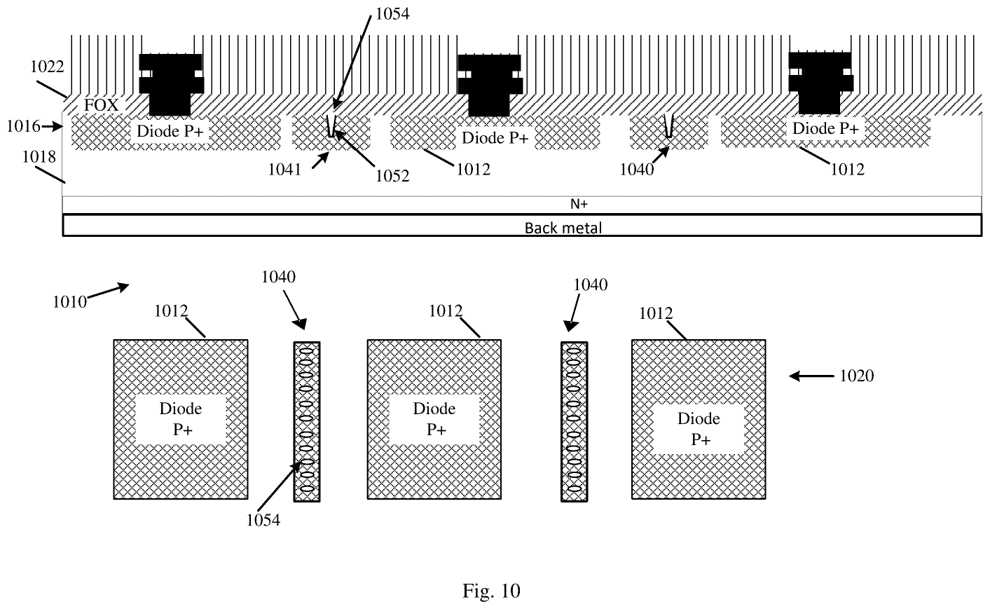

Reference is made to FIG. 10, which schematically illustrates a cross-section view of a sensor die 1010, and a top-view 1020 of a surface region 1016 of the sensor die 1010, in accordance with some demonstrative embodiments. For example, sensor die 110 (FIG. 1) may include one or more elements of sensor die 1010.

In some demonstrative aspects, as shown in FIG. 10, sensor die 1010 may include a plurality of detection diodes 1012, which include a diode material, in the surface region 1016 of a silicon substrate 1018 of the sensor die 1010.

In some demonstrative aspects, as shown in FIG. 10, sensor die 1010 may include a plurality of dummy-diode diffusions 1040 including the diode material.

In some demonstrative aspects, as shown in FIG. 10, the plurality of dummy-diode diffusions 1040 may be in the surface region 1016, for example, between the plurality of detection diodes 1012.

In some demonstrative aspects, as shown in FIG. 10, a dummy-diode diffusion 1041 of the plurality of dummy-diode diffusions 1040, e.g., each dummy-diode diffusion 1040, may include a trench 1052.

In some demonstrative aspects, as shown in FIG. 10, trench 1052 may be substantially in the middle of the dummy-diode diffusion 1041.

In some demonstrative aspects, as shown in FIG. 10, dummy-diode diffusion 1041 may include an aperture 1054 over the trench 1052.

In some demonstrative aspects, as shown in FIG. 10, a FOX layer 1022 may cover the trench 1052.

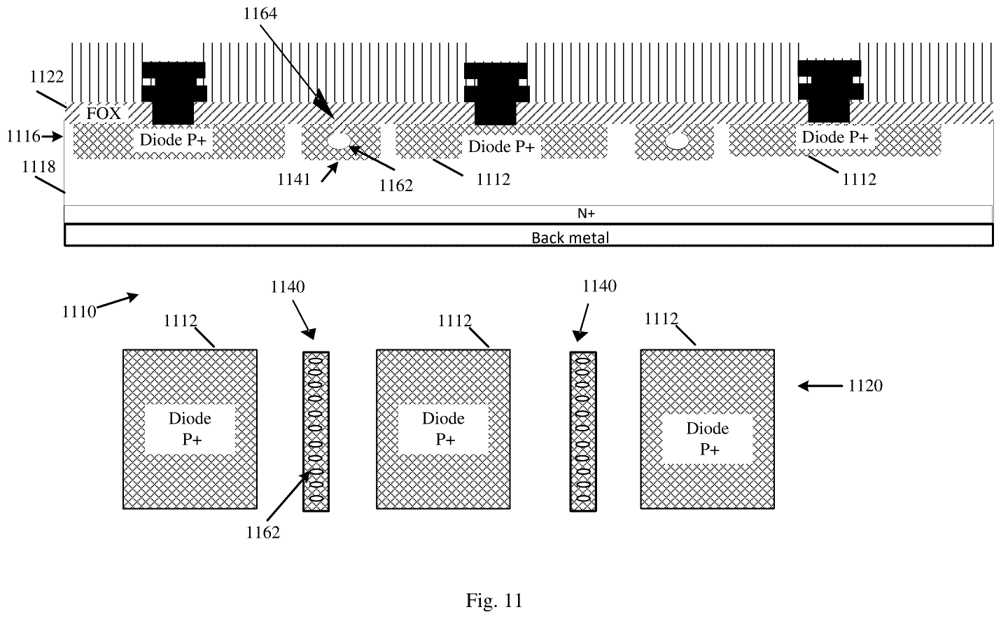

Reference is made to FIG. 11, which schematically illustrates a cross-section view of a sensor die 1110, and a top-view 1120 of a surface region 1116 of the sensor die 1110, in accordance with some demonstrative embodiments. For example, sensor die 110 (FIG. 1) may include one or more elements of sensor die 1110.

In some demonstrative aspects, as shown in FIG. 11, sensor die 1110 may include a plurality of detection diodes 1112, which include a diode material, in the surface region 1116 of a silicon substrate 1118 of the sensor die 1110.

In some demonstrative aspects, as shown in FIG. 11, sensor die 1110 may include a plurality of dummy-diode diffusions 1140 including the diode material.

In some demonstrative aspects, as shown in FIG. 11, the plurality of dummy-diode diffusions 1140 may be in the surface region 1116 of the silicon substrate 1118 of the sensor die 1110 between the plurality of detection diodes 1112.

In some demonstrative aspects, as shown in FIG. 11, a dummy-diode diffusion 1141 of the plurality of dummy-diode diffusions 1140, e.g., each dummy-diode diffusion 1140, may include a bulbous cavity 1162.

In some demonstrative aspects, as shown in FIG. 11, bulbous cavity 1162 may be substantially in the middle of the dummy-diode diffusion 1141.

In some demonstrative aspects, as shown in FIG. 11, dummy-diode diffusion 1141 may include an aperture 1164 over the bulbous cavity 1162.

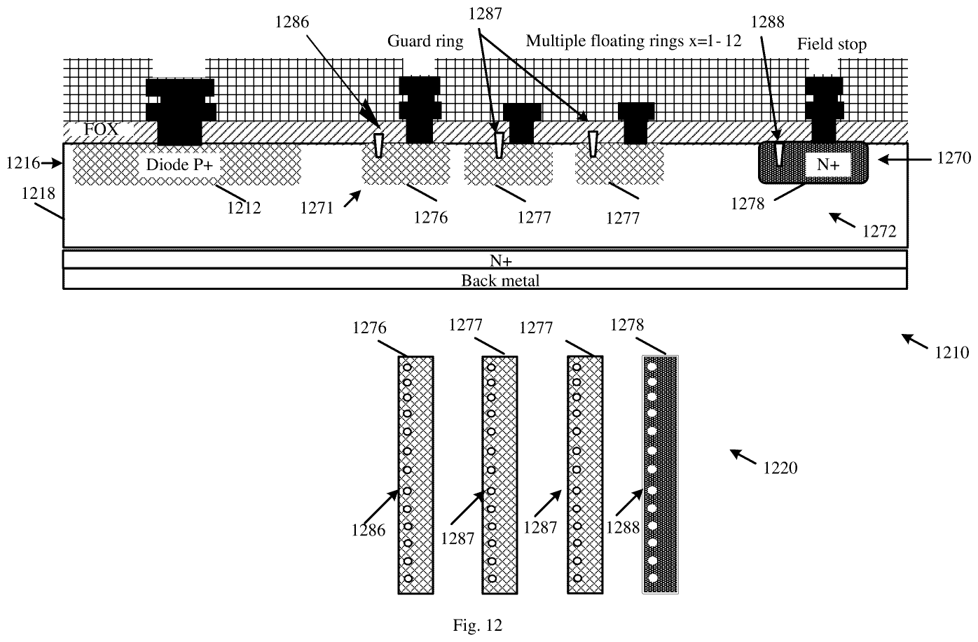

In some demonstrative aspects, as shown in FIG. 11, a FOX layer 1122 may cover the bulbous cavity 1162. Reference is made to FIG. 12, which schematically illustrates a cross-section view of a sensor die 1210 including a termination area 1272, and a top-view of a surface region 1216 of the termination area 1272, in accordance with some demonstrative embodiments. For example, sensor die 110 (FIG. 1) may include one or more elements of sensor die 1210.

In some demonstrative aspects, as shown in FIG. 12, termination area 1272 may include a detection diode 1212, e.g., a termination diode, in the surface region 1216 of a silicon substrate 1218 of the sensor die 1210.

In some demonstrative aspects, as shown in FIG. 12, sensor die 1210 may include a plurality of termination diffusions 1270 in the termination area 1272 of the sensor die 1210.

In some demonstrative aspects, as shown in FIG. 12, the plurality of termination diffusions 1270 may include a collection guard-ring 1276.

In some demonstrative aspects, as shown in FIG. 12, the plurality of termination diffusions 1270 may include one or more floating diffusion rings 1277. For example, the one or more floating diffusion rings 1277 may include a suitable number of floating diffusion rings 1277, e.g., between 1-12 floating diffusion rings 1277, or any other number of floating diffusion rings 1277.

In some demonstrative aspects, as shown in FIG. 12, the plurality of termination diffusions 1270 may include a field stop diffusion 1278.

In some demonstrative aspects, at least one termination diffusion 1270 of the plurality of termination diffusions, e.g., collection guard-ring 1276, a floating diffusion ring 1277, and/or field stop diffusion 1278, may be configured as a contaminant-gettering termination diffusion, for example, to getter metal contaminants from the termination area 1272.

In some demonstrative aspects, the at least one contaminant-gettering termination diffusion 1270 may include a trench, e.g., as described below.

In some demonstrative aspects, as shown in FIG. 12, the collection guard-ring 1276 may be configured as a contaminant-gettering termination diffusion. For example, the collection guard-ring 1276 may include a trench 1286.

In some demonstrative aspects, as shown in FIG. 12, the one or more floating diffusion rings 1277 may be configured as a contaminant-gettering termination diffusion. For example, the one or more floating diffusion rings 1277 may include one or more trenches 1287.

In some demonstrative aspects, as shown in FIG. 12, the field stop diffusion 1278 may be configured as a contaminant-gettering termination diffusion. For example, the field stop diffusion 1278 may include a trench 1288.

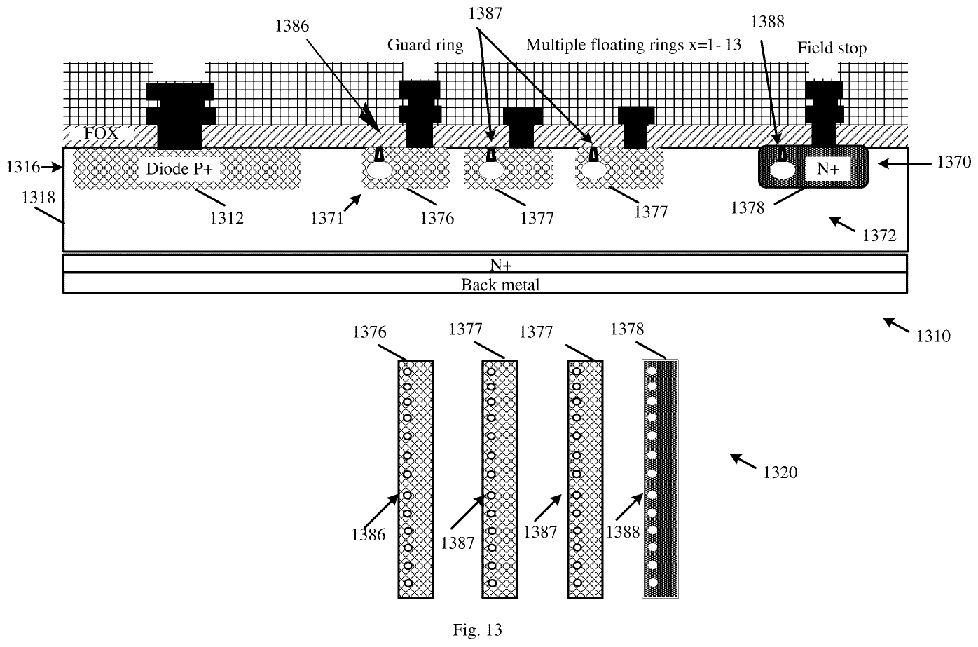

Reference is made to FIG. 13, which schematically illustrates a cross-section view of a sensor die 1310 including a termination area 1372, and a top-view of a surface region 1316 of the termination area 1372, in accordance with some demonstrative embodiments. For example, sensor die 110 (FIG. 1) may include one or more elements of sensor die 1310.

In some demonstrative aspects, as shown in FIG. 13, termination area 1372 may include a detection diode 1312, e.g., a termination diode, in the surface region 1316 of a silicon substrate 1318 of the sensor die 1310.

In some demonstrative aspects, as shown in FIG. 13, sensor die 1310 may include a plurality of termination diffusions 1370 in the termination area 1372 of the sensor die 1310.

In some demonstrative aspects, as shown in FIG. 13, the plurality of termination diffusions 1370 may include a collection guard-ring 1376.

In some demonstrative aspects, as shown in FIG. 13, the plurality of termination diffusions 1370 may include one or more floating diffusion rings 1377. For example, the one or more floating diffusion rings 1377 may include a suitable number of floating diffusion rings 1377, e.g., between 1-12 floating diffusion rings 1377, or any other number of floating diffusion rings 1377.

In some demonstrative aspects, as shown in FIG. 13, the plurality of termination diffusions 1370 may include a field stop diffusion 1378.

In some demonstrative aspects, at least one termination diffusion 1370 of the plurality of termination diffusions, e.g., collection guard-ring 1376, a floating diffusion ring 1377, and/or field stop diffusion 1378, may be configured as a contaminant-gettering termination diffusion, for example, to getter metal contaminants from the termination area 1372.

In some demonstrative aspects, the at least one contaminant-gettering termination diffusion 1370 may include a bulbous cavity, e.g., as described below.

In some demonstrative aspects, as shown in FIG. 13, the collection guard-ring 1376 may be configured as a contaminant-gettering termination diffusion. For example, the collection guard-ring 1376 may include a bulbous cavity 1386.

In some demonstrative aspects, as shown in FIG. 13, the one or more floating diffusion rings 1377 may be configured as a contaminant-gettering termination diffusion. For example, the one or more floating diffusion rings 1377 may include one or more bulbous cavities 1387.

In some demonstrative aspects, as shown in FIG. 13, the field stop diffusion 1378 may be configured as a contaminant-gettering termination diffusion. For example, the field stop diffusion 1378 may include a bulbous cavity 1388.

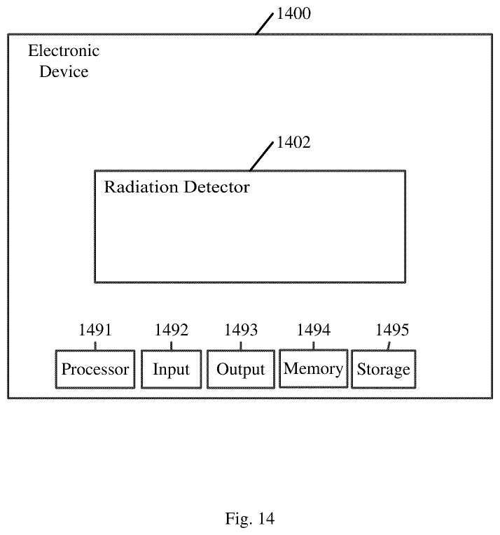

Reference is made to FIG. 14, which schematically illustrates a block diagram of an electronic device 1400, in accordance with some demonstrative aspects.

In some demonstrative aspects, electronic device 1400 may be configured to detect and/or sense ionizing radiation.

In some demonstrative aspects, electronic device 1400 may be configured to determine, process, handle, and/or analyze radiation information with respect to detected ionizing radiation of the ionizing radiation.

In some demonstrative aspects, electronic device 1400 may be configured to store, save, record, maintain, load, and/or retrieve the radiation information.

In some demonstrative aspects, electronic device 1400 may be configured to provide, output, and/or display information based on the radiation information.

In some demonstrative aspects, electronic device 1400 may include a medical device. For example, electronic device 1400 may include a CT scan device, which may be configured to provide CT information based on detected Gamma rays (X-rays).

In some demonstrative aspects, electronic device 1400 may include a nuclear physics device. For example, electronic device 1400 may include a particle detection device of a particle accelerator, which may be configured to provide particle information based on detected high-energy particles.

In some demonstrative aspects, electronic device 1400 may include an aerospace device, a security device, or any other type of device.

In some demonstrative aspects, electronic device 1400 may include a radiation detector 1402, which may be configured to detect the ionizing radiation. For example, radiation detector 1402 may include one or more elements of radiation detector 102 (FIG. 1), and/or may perform one or more operations of radiation detector 102 (FIG. 1).

In some demonstrative aspects, radiation detector 1402 may be configured to convert the ionizing radiation into an electronic signal, which may be utilized for further processing by the electronic device 1400.

In some demonstrative aspects, electronic device 1400 may also include, for example, a processor 1491, an input unit 1492, an output unit 1493, a memory unit 1494, and/or a storage unit 1495. Electronic device 1400 may optionally include other suitable hardware components and/or software components.

In some demonstrative aspects, some or all of the components of electronic device 1400 may be enclosed in a common housing or packaging, and may be interconnected or operably associated using one or more wired or wireless links. In other aspects, components of electronic device 1400 may be distributed among multiple or separate devices.

In some demonstrative aspects, processor 1491 may include, for example, a Central Processing Unit (CPU), a Digital Signal Processor (DSP), one or more processor cores, a single-core processor, a dual-core processor, a multiple-core processor, a microprocessor, a host processor, a controller, a plurality of processors or controllers, a chip, a microchip, one or more circuits, circuitry, a logic unit, an Integrated Circuit (IC), an Application-Specific IC (ASIC), or any other suitable multi-purpose or specific processor or controller. For example, processor 1491 executes instructions, for example, of an Operating System (OS) of electronic device 1400 and/or of one or more suitable applications.

In some demonstrative aspects, memory unit 1494 may include, for example, a Random Access Memory (RAM), a Read Only Memory (ROM), a Dynamic RAM (DRAM), a Synchronous DRAM (SD-RAM), a flash memory, a volatile memory, a non-volatile memory, a cache memory, a buffer, a short term memory unit, a long term memory unit, or other suitable memory units. Storage unit 1495 may include, for example, a hard disk drive, a Solid State Drive (SSD), or other suitable removable or non-removable storage units. For example, memory unit 1494 and/or storage unit 1495, for example, may store data processed by electronic device 1400.

In some demonstrative aspects, input unit 1492 may include, for example, a keyboard, a keypad, a mouse, a touch-screen, a touch-pad, a track-ball, a stylus, a microphone, or other suitable pointing device or input device. Output unit 1493 includes, for example, a monitor, a screen, a touch-screen, a flat panel display, a Light Emitting Diode (LED) display unit, an Organic LED (OLED) display unit, a Liquid Crystal Display (LCD) display unit, a plasma display unit, one or more audio speakers or earphones, or other suitable output devices.

In some demonstrative aspects, processor 1491 may be configured to generate radiation information, for example, based on electronic signals from the radiation detector 1402.

For example, processor 1491 may be configured to store the radiation information in memory unit 1494.

For example, processor 1491 may be configured to control output unit 1493 to provide output information based on the radiation information.

### Examples

The following examples pertain to further aspects.

Example 1 includes an apparatus comprising a sensor die configured to sense ionizing radiation, the sensor die comprising a plurality of pixel sensors configured to sense the ionizing radiation, the plurality of pixel sensors comprising a plurality of detection diodes, wherein the plurality of detection diodes is in a surface region of a silicon substrate of the sensor die, the plurality of detection diodes formed of a diode material; and a plurality of dummy-diode diffusions in the surface region of the silicon substrate, the plurality of dummy-diode diffusions in a plurality of gettering regions between the plurality of detection diodes, the plurality of dummy-diode diffusions comprising the diode material, wherein a dummy-diode diffusion of the plurality of dummy-diode diffusions in a gettering region between two adjacent detection diodes of the plurality of detection diodes is configured to getter metal contaminants from the gettering region, wherein a width of the dummy-diode diffusion is no more than 5 percent of a width of a detection diode of the two adjacent detection diodes.

Example 2 includes the subject matter of Example 1, and optionally, wherein the dummy-diode diffusion comprises a silicided dummy-diode diffusion comprising a dummy-diode portion comprising the diode material; and a silicide layer on the dummy-diode portion.

Example 3 includes the subject matter of Example 2, and optionally, wherein the dummy-diode portion of the silicided dummy-diode diffusion comprises a trench, wherein the silicide layer comprises an aperture over the trench.

Example 4 includes the subject matter of Example 2, and optionally, wherein the dummy-diode portion of the silicided dummy-diode diffusion comprises a bulbous cavity, wherein the silicide layer comprises an aperture over the bulbous cavity.

Example 5 includes the subject matter of Example 2, and optionally, wherein the sensor die comprises a Field Oxide (FOX) layer on the surface region of the silicon substrate, wherein the FOX layer has an opening above the silicided dummy-diode diffusion.

Example 6 includes the subject matter of any one of Examples 2-5, and optionally, wherein the silicide layer is formed of at least one of Cobalt Silicide (CoSi), Titanium Silicide (TiSi), or Nickel Silicide (NiSi).

Example 7 includes the subject matter of Example 1, and optionally, wherein the dummy-diode diffusion comprises a trench.

Example 8 includes the subject matter of Example 7, and optionally, wherein a width of the trench is no more than 1 micron.

Example 9 includes the subject matter of Example 7 or 8, and optionally, wherein a width of the trench is between 0.3 micron and 1 micron.

Example 10 includes the subject matter of any one of Examples 7-9, and optionally, wherein a depth of the trench is no more than 3 micron.

Example 11 includes the subject matter of any one of Examples 7-10, and optionally, wherein a depth of the trench is between 0.5 micron and 3 micron.

Example 12 includes the subject matter of any one of Examples 7-11, and optionally, wherein the trench is substantially in the middle of the dummy-diode diffusion.

Example 13 includes the subject matter of any one of Examples 1-12, and optionally, wherein at least one dummy-diode diffusion of the plurality of dummy-diode diffusion comprises a bulbous cavity.

Example 14 includes the subject matter of any one of Examples 1-13, and optionally, wherein each dummy-diode diffusion of the plurality of dummy-diode diffusions is in a different gettering region between two different adjacent detection diodes of the plurality of detection diodes.

Example 15 includes the subject matter of Example 14, and optionally, wherein the plurality of detection diodes are arranged in a first Two-Dimensional (2D) array, the plurality of dummy-diode diffusions are arranged in a second 2D array.

Example 16 includes the subject matter of Example 15, and optionally, wherein the dummy-diode diffusions in the second 2D array are interleaved with the detection diodes in the first 2D array.

Example 17 includes the subject matter of any one of Examples 1-16, and optionally, wherein the dummy-diode diffusion is at substantially equal distances from the two adjacent detection diodes.

Example 18 includes the subject matter of any one of Examples 1-17, and optionally, wherein the sensor die comprises a plurality of termination diffusions in a termination area of the sensor die, wherein at least one termination diffusion of the plurality of termination diffusions is configured as a contaminant-gettering termination diffusion to getter metal contaminants from the termination area.

Example 19 includes the subject matter of Example 18, and optionally, wherein the contaminant-gettering termination diffusion comprises a trench.

Example 20 includes the subject matter of Example 18 or 19, and optionally, wherein the contaminant-gettering termination diffusion comprises a bulbous cavity.

Example 21 includes the subject matter of any one of Examples 18-20, and optionally, wherein the contaminant-gettering termination diffusion comprises a silicided contaminant-gettering termination diffusion comprising a termination portion; and a silicide layer on the termination portion.

Example 22 includes the subject matter of any one of Examples 18-21, and optionally, wherein the at least one contaminant-gettering termination diffusion comprises a collection guard-ring, a floating diffusion ring, or a field stop diffusion.

Example 23 includes the subject matter of any one of Examples 1-22, and optionally, wherein the sensor die comprises a Field Oxide (FOX) layer on the surface region of the sensor die; a passivation layer on the FOX layer; and a plurality of contacts through the passivation layer and the FOX layer, the plurality of contacts connected to the plurality of detection diodes.

Example 24 includes the subject matter of any one of Examples 1-23, and optionally, wherein the plurality of pixel sensors comprises a plurality of active pixel sensors, wherein an active pixel sensor of the plurality of active pixel sensors comprises electronic circuitry and a detection diode of the plurality of detection diodes, wherein the electronic circuitry is configured to process an electronic signal generated by the detection diode based on detected ionizing radiation.

Example 25 includes the subject matter of any one of Examples 1-24, and optionally, wherein the width of the dummy-diode diffusion is no more than 4 percent of the width of the detection diode.

Example 26 includes the subject matter of any one of Examples 1-25, and optionally, wherein the width of the dummy-diode diffusion is no more than 3 percent of the width of the detection diode.

Example 27 includes the subject matter of any one of Examples 1-26, and optionally, wherein the width of the dummy-diode diffusion is no more than 1 percent of the width of the detection diode.

Example 28 includes the subject matter of any one of Examples 1-27, and optionally, wherein the width of the dummy-diode diffusion is between 3 micron and 10 micron.

Example 29 includes the subject matter of any one of Examples 1-28, and optionally, wherein a depth of the dummy-diode diffusion is no more than 10 micron.

Example 30 includes the subject matter of any one of Examples 1-29, and optionally, wherein a depth of the dummy-diode diffusion is no more than 5 micron.

Example 31 includes the subject matter of any one of Examples 1-30, and optionally, wherein a thickness of the silicon substrate is at least 300 micron.

Example 32 includes the subject matter of any one of Examples 1-31, and optionally, wherein a thickness of the silicon substrate is at least 550 micron.

Example 33 includes the subject matter of any one of Examples 1-32, and optionally, wherein the silicon substrate comprises a Float-Zone (FZ) silicon substrate.

Example 34 includes the subject matter of any one of Examples 1-32, and optionally, wherein the silicon substrate comprises a Czochralski silicon substrate.

Example 35 includes the subject matter of any one of Examples 1-34, and optionally, wherein the silicon substrate comprises a high-resistance silicon substrate.

Example 36 includes the subject matter of any one of Examples 1-35, and optionally, wherein the diode material comprises a heavily doped P-type (P+) material.

Example 37 includes the subject matter of any one of Examples 1-35, and optionally, wherein the diode material comprises a heavily doped N-type (N+) material.

Example 38 includes the subject matter of any one of Examples 1-37, and optionally, comprising a radiation detector to detect the ionizing radiation, the radiation detector comprising the sensor die, and an output to provide radiation information based on detected ionizing radiation.

Example 39 includes an electronic device comprising a radiation detector configured to detect ionizing radiation, the radiation detector comprising a sensor die comprising a plurality of pixel sensors configured to sense the ionizing radiation, the plurality of pixel sensors comprising a plurality of detection diodes, wherein the plurality of detection diodes is in a surface region of a silicon substrate of the sensor die, the plurality of detection diodes formed of a diode material; and a plurality of dummy-diode diffusions in the surface region of the silicon substrate, the plurality of dummy-diode diffusions in a plurality of gettering regions between the plurality of detection diodes, the plurality of dummy-diode diffusions comprising the diode material, wherein a dummy-diode diffusion of the plurality of dummy-diode diffusions in a gettering region between two adjacent detection diodes of the plurality of detection diodes is configured to getter metal contaminants from the gettering region, wherein a width of the dummy-diode diffusion is no more than 5 percent of a width of a detection diode of the two adjacent detection diodes; and an output to provide electronic detection signals based on detected ionizing radiation; a processor to generate radiation information based on the electronic detection signals from the radiation detector; and a memory to store information processed by the processor.

Example 40 includes the electronic device of Example 39, and optionally, including the subject matter of any of Examples 1-38.

Example 41 includes an apparatus comprising means for performing any of the described operations of any of Examples 1-40.

Example 42 includes a method including any of the described operations of any of Examples 1-40.

Functions, operations, components and/or features described herein with reference to one or more aspects, may be combined with, or may be utilized in combination with, one or more other functions, operations, components and/or features described herein with reference to one or more other aspects, or vice versa.

While certain features have been illustrated and described herein, many modifications, substitutions, changes, and equivalents may occur to those skilled in the art. It is, therefore, to be understood that the appended claims are intended to cover all such modifications and changes as fall within the true spirit of the invention.

What is claimed is:

1. An apparatus comprising:
a sensor die configured to sense ionizing radiation, the sensor die comprising:
a plurality of pixel sensors configured to sense the ionizing radiation, the plurality of pixel sensors comprising a plurality of detection diodes, wherein the plurality of detection diodes is in a surface region of a silicon substrate of the sensor die, the plurality of detection diodes formed of a diode material; and
a plurality of dummy-diode diffusions in the surface region of the silicon substrate, the plurality of dummy-diode diffusions in a plurality of gettering regions between the plurality of detection diodes, the plurality of dummy-diode diffusions comprising the diode material, wherein a dummy-diode diffusion of the plurality of dummy-diode diffusions in a gettering region between two adjacent detection diodes of the plurality of detection diodes is configured to getter metal contaminants from the gettering region, wherein a width of the dummy-diode diffusion is no more than 5 percent of a width of a detection diode of the two adjacent detection diodes.

2. The apparatus of claim 1, wherein the dummy-diode diffusion comprises a silicided dummy-diode diffusion comprising:
a dummy-diode portion comprising the diode material; and
a silicide layer on the dummy-diode portion.

3. The apparatus of claim 2, wherein the dummy-diode portion of the silicided dummy-diode diffusion comprises a trench, wherein the silicide layer comprises an aperture over the trench.

4. The apparatus of claim 2, wherein the dummy-diode portion of the silicided dummy-diode diffusion comprises a bulbous cavity, wherein the silicide layer comprises an aperture over the bulbous cavity.

5. The apparatus of claim 2, wherein the sensor die comprises a Field Oxide (FOX) layer on the surface region of the silicon substrate, wherein the FOX layer has an opening above the silicided dummy-diode diffusion.

6. The apparatus of claim 2, wherein the silicide layer is formed of at least one of Cobalt Silicide (CoSi), Titanium Silicide (TiSi), or Nickel Silicide (NiSi).

7. The apparatus of claim 1, wherein the dummy-diode diffusion comprises a trench.

8. The apparatus of claim 7, wherein a width of the trench is no more than 1 micron.

9. The apparatus of claim 7, wherein a depth of the trench is no more than 3 micron.

10. The apparatus of claim 1, wherein at least one dummy-diode diffusion of the plurality of dummy-diode diffusion comprises a bulbous cavity.

11. The apparatus of claim 1, wherein each dummy-diode diffusion of the plurality of dummy-diode diffusions is in a different gettering region between two different adjacent detection diodes of the plurality of detection diodes.

12. The apparatus of claim 1, wherein the dummy-diode diffusion is at substantially equal distances from the two adjacent detection diodes.

13. The apparatus of claim 1, wherein the sensor die comprises a plurality of termination diffusions in a termination area of the sensor die, wherein at least one termination diffusion of the plurality of termination diffusions is configured as a contaminant-gettering termination diffusion to getter metal contaminants from the termination area.

14. The apparatus of claim 13, wherein the contaminant-gettering termination diffusion comprises a silicided contaminant-gettering termination diffusion comprising:
a termination portion; and
a silicide layer on the termination portion.

15. The apparatus of claim 1, wherein the sensor die comprises:
a Field Oxide (FOX) layer on the surface region of the sensor die;
a passivation layer on the FOX layer, and
a plurality of contacts through the passivation layer and the FOX layer, the plurality of contacts connected to the plurality of detection diodes.

16. The apparatus of claim 1, wherein the plurality of pixel sensors comprises a plurality of active pixel sensors, wherein an active pixel sensor of the plurality of active pixel sensors comprises electronic circuitry and a detection diode of the plurality of detection diodes, wherein the electronic circuitry is configured to process an electronic signal generated by the detection diode based on detected ionizing radiation.

17. The apparatus of claim 1, wherein the width of the dummy-diode diffusion is no more than 3 percent of the width of the detection diode.

18. The apparatus of claim 1, wherein a depth of the dummy-diode diffusion is no more than 10 micron.

19. The apparatus of claim 1, wherein a thickness of the silicon substrate is at least 300 micron.

20. The apparatus of claim 1, wherein the silicon substrate comprises a Float-Zone (FZ) silicon substrate.

21. The apparatus of claim 1, wherein the silicon substrate comprises a Czochralski silicon substrate.

22. The apparatus of claim 1 comprising a radiation detector to detect the ionizing radiation, the radiation detector comprising the sensor die, and an output to provide radiation information based on detected ionizing radiation.

23. An electronic device comprising:
a radiation detector configured to detect ionizing radiation, the radiation detector comprising:
a sensor die comprising:
a plurality of pixel sensors configured to sense the ionizing radiation, the plurality of pixel sensors comprising a plurality of detection diodes, wherein the plurality of detection diodes is in a surface region of a silicon substrate of the sensor die, the plurality of detection diodes formed of a diode material; and
a plurality of dummy-diode diffusions in the surface region of the silicon substrate, the plurality of dummy-diode diffusions in a plurality of gettering regions between the plurality of detection diodes, the plurality of dummy-diode diffusions comprising the diode material, wherein a dummy-diode diffusion of the plurality of dummy-diode diffusions in a gettering region between two adjacent detection diodes of the plurality of detection diodes is configured to getter metal contaminants from the gettering region, wherein a width of the dummy-diode diffusion is no more than 5 percent of a width of a detection diode of the two adjacent detection diodes; and
an output to provide electronic detection signals based on detected ionizing radiation;
a processor to generate radiation information based on the electronic detection signals from the radiation detector; and
a memory to store information processed by the processor.

24. The electronic device of claim 23, wherein the dummy-diode diffusion comprises a silicided dummy-diode diffusion comprising:
a dummy-diode portion comprising the diode material; and
a silicide layer on the dummy-diode portion.
